(19) United States
(12) Patent Application Publication
(10) Pub. No.: US 2024/0427763 A1
(43) Pub. Date: Dec. 26, 2024

(54) DESIGN AUTOMATION METHOD AND APPARATUS USING GENERATIVE NATURAL LANGUAGE MODEL

(71) Applicant: UIF (UNIVERSITY INDUSTRY FOUNDATION), YONSEI UNIVERSITY, Seoul (KR)

(72) Inventors: Ghang LEE, Seoul (KR); Su Hyung JANG, Seoul (KR)

(73) Assignee: UIF (UNIVERSITY INDUSTRY FOUNDATION), YONSEI UNIVERSITY, Seoul (KR)

(21) Appl. No.: 18/747,003

(22) Filed: Jun. 18, 2024

(30) Foreign Application Priority Data
Jun. 21, 2023 (KR) 10-2023-0079943

(51) Int. Cl. G06F 16/2452; G06F 16/21

(52) U.S. Cl. CPC G06F 16/24522; G06F 16/211

(57) ABSTRACT

A design automation method according to the present disclosure includes receiving a task prompt which is a text expressing a design authoring task to be performed with a natural language, from a user, acquiring structured data from the generative natural language model by inputting the task prompt to a trained generative natural language model with a natural language as an input and structured data as an output, and acquiring the design result from design software by inputting the acquired structured data to the design software.

### BACKGROUND

### Field

The present disclosure relates to a method and an apparatus for automating a design authoring task through a design software.

### Description of the Related Art

In order to utilize design software in the related art, not only expert understanding about a design process and decision making, but also a technical understanding about how to define and how to edit an object and a property thereof in the design software are requested.

That is, the design authoring method of the related art is a process of allowing designers to understand functions implemented in the design software in addition to their expert knowledge in the field and repeatedly and manually create and modify objects and object properties defined in the design software according to judgement based on the expert knowledge to create results to be designed.

Currently, design automation by utilizing software is possible through rule-based automation for a specific design authoring task. However, the rule-based automation is targeted at specific design software and specific design authoring tasks within a predetermined range, which makes it less versatile. Further, there is a problem in that it takes a lot of time and efforts for the designers to learn about the function of the design software in addition to the expert knowledge.

### SUMMARY

An object to be achieved by the present disclosure is to provide a method and an apparatus for design automation using a generative natural language model which can be utilized for versatile purposes without being limited to specific design software and design authoring tasks within a predetermined range and reduce designer's time and effort to learn about the function of the design software.

The technical object to be achieved by the present disclosure is not limited to the above-mentioned technical objects, and other technical objects, which are not mentioned above, can be clearly understood by those skilled in the art from the following descriptions.

In order to achieve the above-described technical objects, according to an aspect of the present disclosure, a design automation method includes receiving a task prompt which is a text expressing a design authoring task to be performed with a natural language, from a user; acquiring structured data from the generative natural language model by inputting the task prompt to a trained generative natural language model with a natural language as an input and structured data as an output; and acquiring the design result from design software by inputting the acquired structured data to the design software.

A purpose of the design authoring task includes generation of an object or modification of an object and in the acquiring of structured data, a purpose, a target object, and a necessary property of the design authoring task are identified by the generative natural language model and the structure data is acquired thereby.

When the purpose of the design authoring task is to modify the object, information about an object to be modified is additionally input to the generative natural language model.

The generative natural language model is finely tuned so as to output structured data which is understandable by the design software from the natural language input.

The generative natural language model is pre-trained, but is not finely tuned and in the acquiring of structured data, an instruction prompt to set a type and a form of the structured data is input to the generative natural language model in addition to the task prompt.

The structured data has a previously defined data schema structure.

The structured data is a database table, Excel sheets, JSON, or XML data.

In order to achieve the above-described technical objects, according to another aspect of the present disclosure, a computer program is stored in a computer readable storage medium to allow a computer to execute the design automation method.

In order to achieve the above-described technical objects, according to another aspect of the present disclosure, a design automation apparatus includes an input/output interface which receives a task prompt which is a text expressing a design authoring task to be performed with a natural language, from a user; and a processor which acquires a design result from the task prompt, and the processor is configured to acquire structured data from the generative natural language model by inputting the task prompt to a trained generative natural language model with a natural language as an input and structured data as an output and acquire the design result from design software by inputting the acquired structured data to the design software.

A purpose of the design authoring task includes generation of an object or modification of an object and the processor identifies a purpose, a target object, and a necessary property of the design authoring task by the generative natural language model and acquires the structure data thereby.

When the purpose of the design authoring task is to modify the object, information about an object to be modified is additionally input to the generative natural language model.

The generative natural language model is finely tuned so as to output structured data which is understandable by the design software from the natural language input.

The generative natural language model is pre-trained, but is not finely tuned and the processor inputs an instruction prompt to set a type and a form of the structured data to the generative natural language model in addition to the task prompt.

According to the present disclosure described above, it is possible to provide a method and an apparatus for design automation using a generative natural language model which can be utilized for versatile purposes without being limited to specific design software and design authoring tasks within a predetermined range and shorten designer's time and effort to learn about the function of the design software.

Effects of the present disclosure are not limited to the above-mentioned effects, and other effects, which are not mentioned above, can be clearly understood by those skilled in the art from the following descriptions.

### BRIEF DESCRIPTION OF THE DRAWINGS

FIG. 1 is a block diagram illustrating a design automation apparatus according to exemplary embodiments of the present disclosure;

FIG. 2 illustrates an operation of a design automation apparatus according to an exemplary embodiment of the present disclosure;

FIG. 3 illustrates a flowchart of a design automation method according to an exemplary embodiment of the present disclosure;

FIG. 4 illustrates an example of a task prompt input from a user;

FIG. 5 illustrates another example of a task prompt input from a user;

FIG. 6 illustrates an example of structured data acquired from a generative natural language model;

FIG. 7 is a specific example of step S320 of FIG. 3;

FIG. 8 illustrates an operation of a design automation apparatus according to another exemplary embodiment of the present disclosure;

FIG. 9 illustrates a flowchart of a design automation method according to another exemplary embodiment of the present disclosure;

FIG. 10 illustrates an example of an instruction prompt; and

FIG. 11 is a specific example of step S930 of FIG. 9.

### DETAILED DESCRIPTION OF THE EMBODIMENT

Hereinafter, exemplary embodiments of the present disclosure will be described in detail with reference to the drawings. Substantially same components in the following description and the accompanying drawings may be denoted by the same reference numerals so that a redundant description will be omitted. Further, in the description of the exemplary embodiment, if it is considered that specific description of related known configuration or function may cloud the gist of the present disclosure, the detailed description thereof will be omitted.

A recently proposed generative natural language model shows a high performance in processing and generating not only structured data which cane processed through existing language models, but also unstructured data. Additionally, a generative language model learned through a large amount of data presupposes the possibility of generating and processing the data used for learning. Therefore, the generative language model not only creates news articles, non-literature, and computer program codes, but also processes and generates natural languages based on background knowledge in expert fields, such as passing of US medical licensing and law school exams. Inspired by this, the present disclosure proposes a design automation method and apparatus which allow a designer to explain design authoring tasks to be performed based on interaction with a computer system utilizing a natural language and automate a design authoring process through a generative natural language model based thereon.

In the exemplary embodiments of the present disclosure, design results refer to digital data including information about two-dimensional or three-dimensional objects to express a design object and properties thereof. Further, the design authoring process refers to a process of generating, modifying, and deleting required objects and properties thereof by utilizing design software to create a design result.

In the exemplary embodiments to be described below, for the sake of convenience, even though a building information modeling design will be described as a target, the present disclosure is applicable to various fields which require expertise for design, such as architecture, civil engineering, plants, machinery, and electricity and has software for experts, but is not limited to a specific design software.

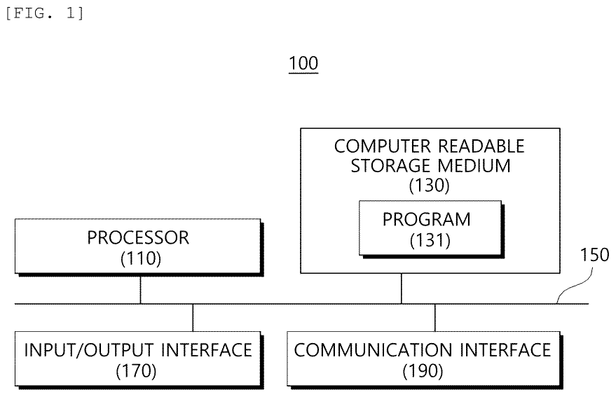

FIG. 1 is a block diagram illustrating a design automation apparatus according to exemplary embodiments of the present disclosure.

The design automation apparatus 100 may include one or more processors 110, a computer readable storage medium 130, and a communication bus 150.

The processor 110 controls the design automation apparatus 100 to operate. For example, the processor 110 may execute one or more programs 131 stored in the computer readable storage medium 130. One or more programs 131 include one or more computer executable instructions and when the computer executable instruction is executed by the processor 110, the computer executable instruction may be configured to allow the design automation apparatus 100 to perform an operation for automating a design authoring process by means of a generative natural language model.

The computer readable storage medium 130 is configured to store a computer executable instruction or program code, program data and/or other appropriate format of information to automate a design authoring process by means of the generative natural language model. The program 131 stored in the computer readable storage medium 130 includes a set of instructions executable by the processor 110. In one exemplary embodiment, the computer readable storage medium 130 may be a memory (a volatile memory such as a random access memory, a non-volatile memory, or an appropriate combination thereof), one or more magnetic disk storage devices, optical disk storage devices, flash memory devices, and another format of storage media which are accessed by the design automation apparatus 100 and store desired information, or an appropriate combination thereof.

The communication bus 150 interconnects various other components of the design automation apparatus 100 including the processor 110 and the computer readable storage medium 130 to each other.

The design automation apparatus 100 may include one or more input/output interfaces 170 and one or more communication interfaces 190 which provide an interface for one or more input/output devices. The input/output interface 170 and the communication interface 190 are connected to the communication bus 150. The input/output device (not illustrated) may be connected to the other components of the design automation apparatus 100 by means of the input/output interface 170.

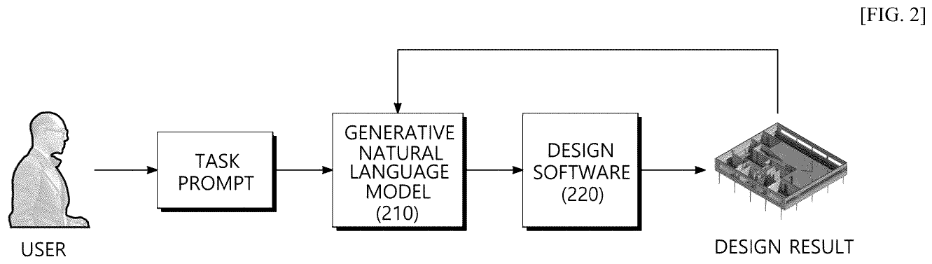

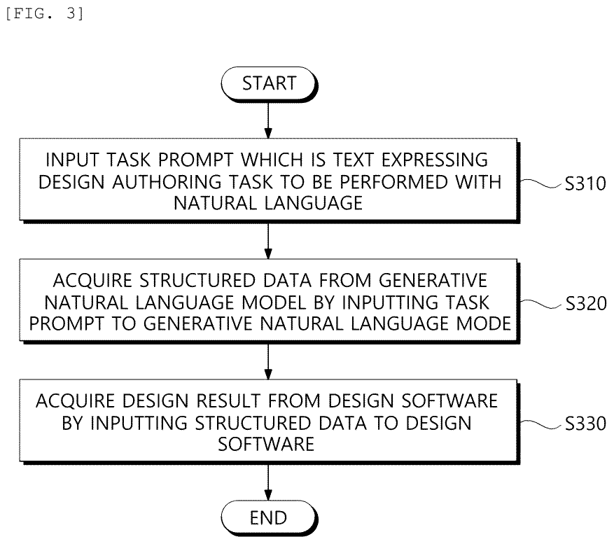

FIG. 2 illustrates an operation of a design automation apparatus according to an exemplary embodiment of the present disclosure and FIG. 3 illustrates a flowchart of a design automation method according to an exemplary embodiment of the present disclosure, corresponding to FIG. 2.

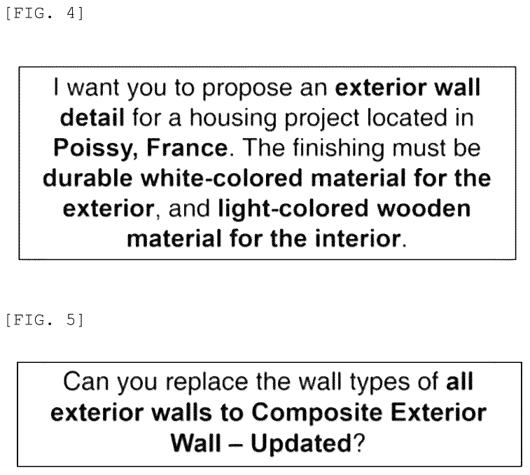

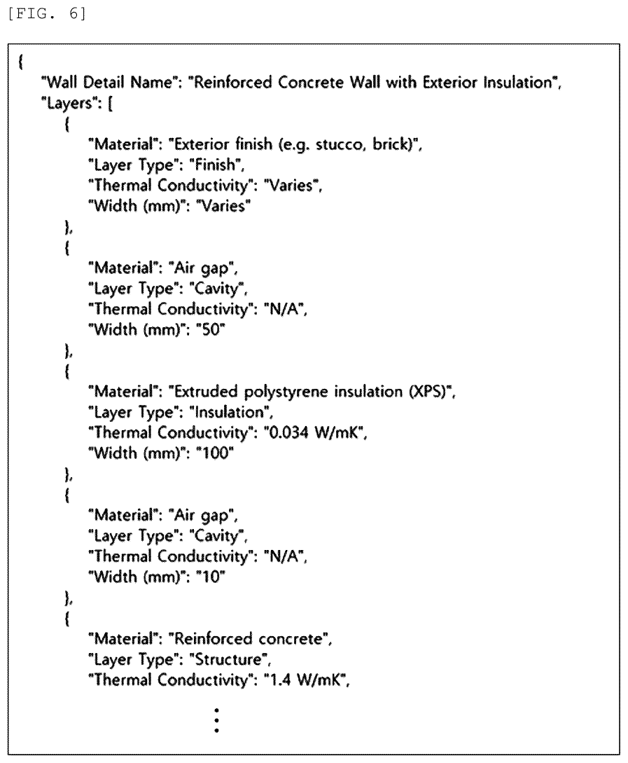

Referring to FIGS. 2 and 3, in step S310, the input/output interface 170 receives a task prompt which is a text in which a design authoring task to be performed is expressed with natural languages, from a user. Here, a purpose of a design authoring task includes generation of an object or modification of an object (which has been generated). FIG. 4 is an example of a task prompt which is input from the user to modify the object. FIG. 5 is another example of a task prompt which is input from the user to modify the object. The task prompt is input by means of interaction with the user, using a conversational agent.

Next, in step S320, the processor 110 inputs the task prompt to the generative natural language model 210 to acquire structured data from the generative natural language model 210. The generative natural language model 210 may be an artificial intelligence model trained with a natural language as an input and structured data as an output. Here, the structured data is data which is configured in accordance with a predetermined format to be stored and is easily analyzed and has a previously defined data schema structure, which makes it easy to search and analyze and ensure data consistency and accuracy. The structured data may be, for example, a database table, Excel sheets, JSON, or XML data. The generative natural language model 210 may be an artificial intelligence model which is finely-tuned to output structured data which can be understood by the design software 220, from the task prompt, after being pre-trained.

Specifically, in step S320, the processor 110 may identify a purpose, a target object, and necessary property of a design authoring task, by means of the generative natural language model 210 and acquire structured data accordingly, Here, when a purpose of the design authoring task is modification, information about an object to be modified is additionally input to the generative natural language model 210 from a design result, together with the task prompt.

FIG. 6 is an example of JSON data, as an example of structured data acquired from the generative natural language model 210.

Next, in step S330, the processor 110 inputs structured data to the design software 220 to acquire a design result from the design software 220. The design result acquired from the design software 220 may be output through the input/output interface 170 to be identified by the user.

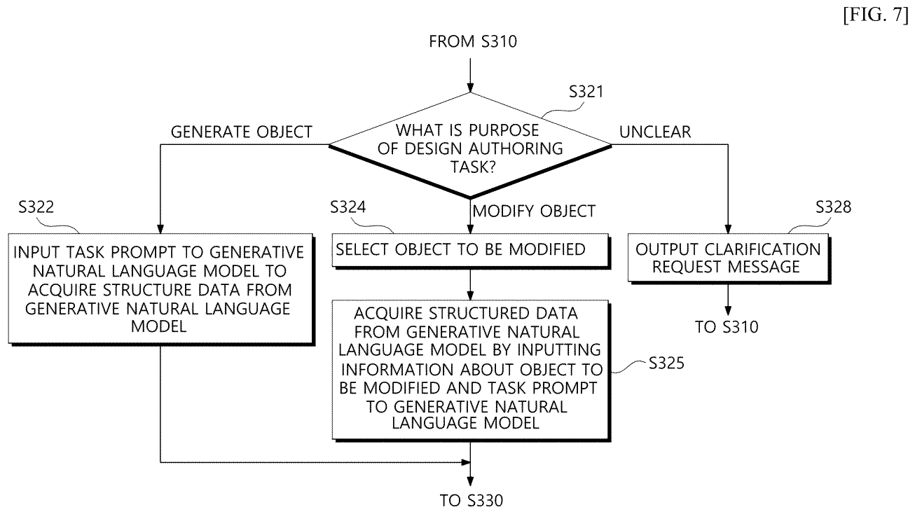

FIG. 7 is a specific example of step S320 of FIG. 3.

In step S321, the processor 110 analyzes the task prompt to identify the purpose of the design authoring task.

When a purpose of the design authoring task is to generate an object, in step S322, the processor 110 inputs a task prompt to the generative natural language model 210 to acquire structured data from the generative natural language model 210. Here, the acquired structured data includes information about an object to be generated and a property to be generated.

When a purpose of the design authoring task is to modify an object, in step S324, the processor 110 may select an object to be modified from a design result based on the task prompt or user's choice.

Next, in step S325, the processor 110 inputs information about the object to be modified and the task prompt to the generative natural language model 210 to acquire structured data from the generative natural language model 210. Here, the acquired structured data includes information about an object to be modified and a property to be modified.

When a purpose of the design authoring task is unclear, in step S328, the processor 110 outputs a message requesting to clarify a design authoring ask through the input/output interface 170 and returns to step S310 to receive the task prompt again.

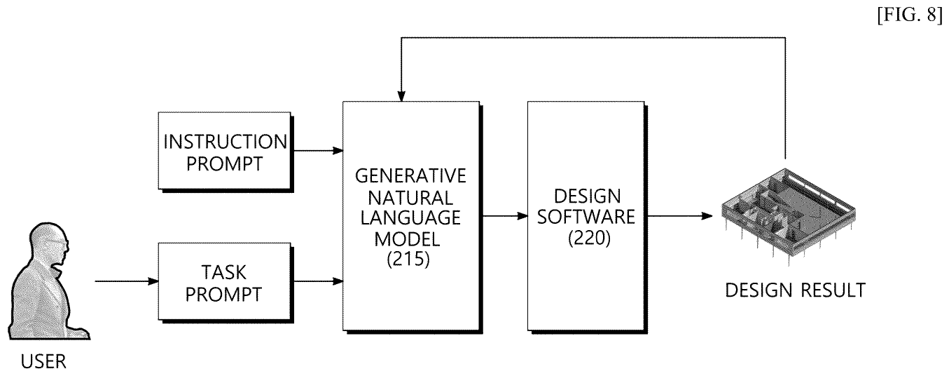

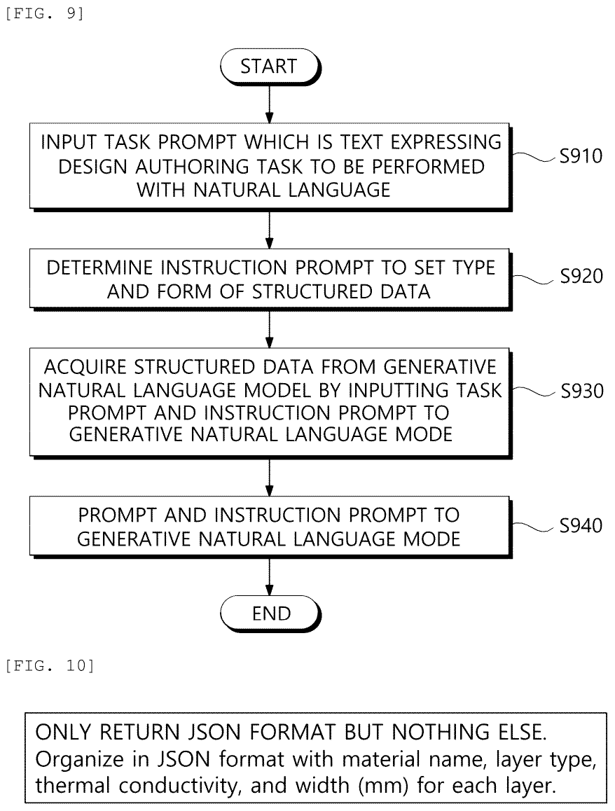

FIG. 8 illustrates an operation of a design automation apparatus according to another exemplary embodiment of the present disclosure and FIG. 9 illustrates a flowchart of a design automation method according to another exemplary embodiment of the present disclosure, corresponding to FIG. 8. In the description of th exemplary embodiment of FIGS. 8 and 9, repeated description with the exemplary embodiment of FIGS. 2 and 3 will be omitted.

In the present exemplary embodiment, a generative natural language model 215 may be an artificial intelligence model which is pre-trained, but is not finely-tuned to output structured data which can be understood by the design software 220. Accordingly, in the present exemplary embodiment, an instruction prompt to set a type and a form of structured data is additionally input to the generative natural language model 215 to output structured data which can be understood by the design software 220 by means of the generative natural language model 215.

Referring to FIGS. 8 and 9, in step S910, the input/output interface 170 receives a task prompt which is a text expressing a design authoring task to be performed with natural languages, from a user.

In step S920, the processor 110 determines an instruction prompt to set a type and a form of the structured data. The instruction prompt may be input from the user through the input/output interface 170 or may be defined in advance according to the design software 220. Further, the instruction prompt may be determined according to a purpose and a target object of the design authoring task which is identified by analyzing the task prompt.

FIG. 10 illustrates an example of an instruction prompt. Referring to FIG. 10, the instruction prompt may describe to output data in JSON format and a form of the JSON data.

Next, in step S930, the processor 110 inputs the task prompt and the instruction prompt to the generative natural language model 215 to acquire structured data from the generative natural language model 215. The generative natural language model 215 is not finely tuned to output structured data which can be understood by the design software 220, but outputs structured data which can be understood by the design software 220 from the task prompt by inputting the task prompt and the instruction prompt together.

Next, in step S940, the processor 110 inputs the structured data to the design software 220 to acquire a design result from the design software 220. The design result acquired from the design software 220 may be output through the input/output interface 170 to be identified by the user.

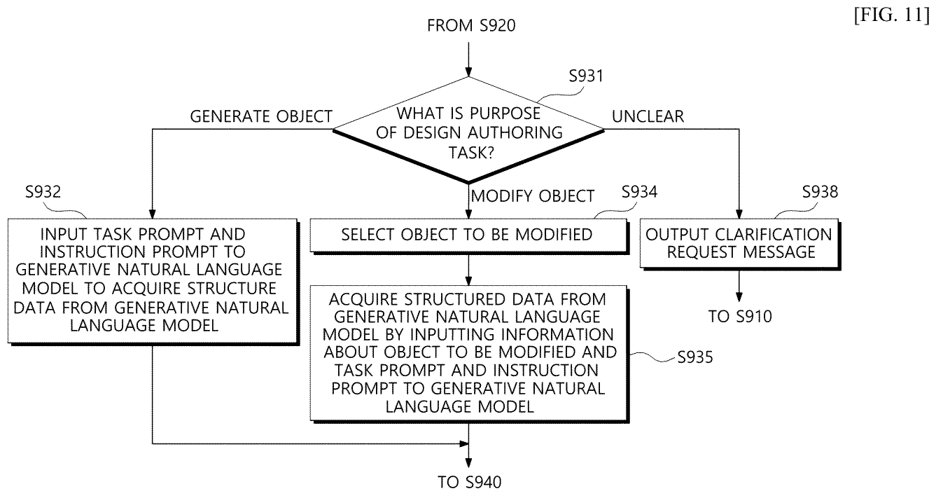

FIG. 11 is a specific example of step S930 of FIG. 9.

In step S931, the processor 110 analyzes the task prompt to identify the purpose of the design authoring task.

When the purpose of the design authoring task is to generate an object, in step S932, the processor 110 inputs a task prompt and an instruction prompt to the generative natural language model 215 to acquire structured data from the generative natural language model 215. Here, the acquired structured data includes information about an object to be generated and a property to be generated.

When a purpose of the design authoring task is to modify an object, in step S934, the processor 110 may select an object to be modified from a design result based on the task prompt or user's choice.

Next, in step S935, the processor 110 inputs information about the object to be modified, the task prompt, and the instruction prompt to the generative natural language model 215 to acquire structured data from the generative natural language model 215. Here, the acquired structured data includes information about an object to be modified and a property to be modified.

When a purpose of the design authoring task is unclear, in step S938, the processor 110 outputs a message requesting to clarify a design authoring ask through the input/output interface 170 and returns to step S910 to receive the task prompt again.

A design project management method which introduces design software may contribute to improving productivity, but the cost and time to introduce this become the biggest obstacles. According to the exemplary embodiments of the present disclosure, a designer may automate the design authoring task by explaining the design authoring task in natural languages with expert knowledge for the design without learning about the function and the application of the design software. Accordingly, the exemplary embodiments of the present disclosure may greatly contribute to spread of design digitalization in each industry and improvement of productivity by lowering the barrier to introduction of the design software.

The design automation apparatus according to the exemplary embodiments of the present disclosure may be implemented in a logic circuit by hardware, firm ware, software, or a combination thereof or may be implemented using a general purpose or special purpose computer. The apparatus may be implemented using hardwired device, field programmable gate array (FPGA) or application specific integrated circuit (ASIC). Further, the apparatus may be implemented by a system on chip (SoC) including one or more processors and a controller.

The design automation apparatus according to the exemplary embodiments of the present disclosure may be mounted in a computing device or a server provided with a hardware element as a software, a hardware, or a combination thereof. The computing device or server may refer to various devices including all or some of a communication device for communicating with various devices and wired/wireless communication networks such as a communication modem, a memory which stores data for executing programs, and a microprocessor which executes programs to perform operations and commands.

The design automation apparatus according to the exemplary embodiments of the present disclosure may be implemented as a program command which may be executed by various computers to be recorded in a computer readable medium. The computer readable medium indicates an arbitrary medium which participates to provide a command to a processor for execution. The computer readable medium may include solely a program command, a data file, and a data structure or a combination thereof. For example, the computer readable medium may include a magnetic medium, an optical recording medium, and a memory. The computer program may be distributed on a networked computer system so that the computer readable code may be stored and executed in a distributed manner. Functional programs, codes, and code segments for implementing the present embodiment may be easily inferred by programmers in the art to which this embodiment belongs.

The present embodiments are provided to explain the technical spirit of the present embodiment and the scope of the technical spirit of the present embodiment is not limited by these embodiments. The protection scope of the present embodiments should be interpreted based on the following appended claims and it should be appreciated that all technical spirits included within a range equivalent thereto are included in the protection scope of the present embodiments.

What is claimed is:

1. A design automation method, comprising:
receiving a task prompt which is a text expressing a design authoring task to be performed with a natural language, from a user;
acquiring structured data from the generative natural language model by inputting the task prompt to a trained generative natural language model with a natural language as an input and the structured data as an output; and
acquiring a design result from design software by inputting the acquired structured data to the design software.

2. The design automation method according to claim 1, wherein a purpose of the design authoring task includes generation of an object or modification of an object and
in the acquiring of structured data, a purpose, a target object, and a necessary property of the design authoring task are identified by the generative natural language model and the structure data is acquired thereby.

3. The design automation method according to claim 2, wherein when the purpose of the design authoring task is to modify the object, information about an object to be modified is additionally input to the generative natural language model.

4. The design automation method according to claim 1, wherein the generative natural language model is finely tuned so as to output structured data which is understandable by the design software from the natural language input.

5. The design automation method according to claim 1, wherein the generative natural language model is pre-trained, but is not finely tuned and
in the acquiring of structured data, an instruction prompt to set a type and a form of the structured data is input to the generative natural language model in addition to the task prompt.

6. The design automation method according to claim 1, wherein the structured data has a previously defined data schema structure.

7. The design automation method according to claim 6, wherein the structured data is a database table, Excel sheets, JSON, or XML data.

8. A computer program which is stored in a computer readable storage medium to allow a computer to execute the design automation method of claim 1.

9. A design automation apparatus, comprising:
an input/output interface which receives a task prompt which is a text expressing a design authoring task to be performed with a natural language, from a user; and
a processor which acquires a design result from the task prompt,
wherein the processor is configured to acquire structured data from the generative natural language model by inputting the task prompt to a trained generative natural language model with a natural language as an input and structured data as an output; and acquire the design result from design software by inputting the acquired structured data to the design software.

10. The design automation apparatus according to claim 9, wherein a purpose of the design authoring task includes generation of an object or modification of an object and the processor identifies a purpose, a target object, and a necessary property of the design authoring task by the generative natural language model and acquires the structure data thereby.

11. The design automation apparatus according to claim 10, wherein when the purpose of the design authoring task is to modify the object, information about an object to be modified is additionally input to the generative natural language model.

12. The design automation apparatus according to claim 9, wherein the generative natural language model is finely tuned so as to output structured data which is understandable by the design software from the natural language input.

13. The design automation apparatus according to claim 9, wherein the generative natural language model is pre-trained, but is not finely tuned and the processor inputs an instruction prompt to set a type and a form of the structured data to the generative natural language model in addition to the task prompt.

14. The design automation apparatus according to claim 9, wherein the structured data has a previously defined data schema structure.

15. The design automation apparatus according to claim 14, wherein the structured data is a database table, Excel sheets, JSON, or XML data.
